(19) United States
(12) Patent Application Publication
(10) Pub. No.: US 2026/0087212 A1
(43) Pub. Date: Mar. 26, 2026

(54) HYBRID APPROACH TO PREDICTIVE CORROSION/EROSION FOR TUBULAR INTEGRITY MANAGEMENT

(71) Applicant: Landmark Graphics Corporation, Houston, TX (US)

(72) Inventors: Yogesh Bansal, Houston, TX (US); Rachit Kedia, Dubai (AE); Ghazanfar Shahid, Dubai (AE); Christophe Abdon Van Laer, Abu Dhabi (AE)

(21) Appl. No.: 19/022,704

(22) Filed: Jan. 15, 2025

Related U.S. Application Data
(60) Provisional application No. 63/697,150, filed on Sep. 20, 2024.

(51) Int. Cl. G06F 30/28

(52) U.S. Cl. CPC G06F 30/28

(57) ABSTRACT

A method for managing integrity of a tubular comprises obtaining fluid transportation system data, wherein the tubular is a component within a fluid transportation system. The method comprises determining, via a mechanistic model, a mechanistic corrosion rate of the tubular based on the fluid transportation system data. The method comprises determining, via a learning machine, a residual corrosion rate of the tubular based on the fluid transportation system data. The method comprises determining, via a hybrid model, a final corrosion rate of the tubular based on the mechanistic corrosion rate and the residual corrosion rate.

### FIELD

Some implementations relate generally to the field of hydrocarbon recovery and transportation operations and more particularly to the field of managing tubular integrity during transportation of fluids produced from a reservoir.

### BACKGROUND

In hydrocarbon recovery operations, fluid may be produced from a reservoir to the surface, via a wellbore. The fluid produced may include water, oil, gas, and other components such as acidic gases (e.g., carbon dioxide (CO2), hydrogen sulfide (H2S), and other organic acids). These gases, when dissolved in water (if present), may contribute to corrosion, which may compromise the integrity of tubulars in the wellbore and/or on the surface. Instances of tubular corrosion may include anodic reactions (oxidation of iron such as when iron loses electrons and forms iron ferrous ions), cathodic reactions (reduction at the cathode such as CO2 hydration, carbonic acid dissociation, and bicarbonate ion dissociation), etc. Several reactions may occur simultaneously.

### BRIEF DESCRIPTION OF THE DRAWINGS

Implementation of the disclosure may be better understood by referencing the accompanying drawings.

FIG. 1 is a diagrammatic illustration of an example well system, according to some implementations.

FIG. 2 is a block diagram of a hybrid approach for determining the final corrosion rate of a tubular, according to some implementations.

FIG. 3 is a flowchart of example operations for determining a final corrosion rate of a tubular, according to some implementations.

FIG. 4 is a flowchart depicting example operations to configure a learning machine, according to some implementations.

FIG. 5 is a flowchart depicting example operations to train a learning machine, according to some implementations.

FIG. 6 is a chart depicting the incremental learning performance of a learning machine, according to some implementations.

FIG. 7 is a chart depicting the performance of a learning machine, according to some implementations.

FIG. 8 is a chart depicting the performance of a learning machine, according to some implementations.

FIG. 9 is a block diagram depicting an example computer, according to some implementations.

### DESCRIPTION

The description that follows includes example systems, methods, techniques, and program flows that embody aspects of the disclosure. However, it is understood that this disclosure may be practiced without these specific details. For instance, this disclosure refers to determining the corrosion rate of a tubular in a wellbore. Aspects of this disclosure can also be applied to any other suitable tubular on or beneath the Earth's surface and utilized for transporting fluid. For clarity, some well-known instruction instances, protocols, structures, and techniques have been omitted.

Example implementations relate to determining the corrosion/erosion rate of a tubular. A fluid transportation system, such as the tubulars (casing, production tubing, injection tubing, etc.) within a wellbore transporting fluids (water, oil, gas, etc.) to or from the surface, a fluid gathering system on the Earth's surface, a pipeline system, etc. may experience corrosion in the proper conditions, such as when water and acidic gases (CO2, H2S, etc.) are present in the fluid. Detection of corrosion may assist in developing operations to mitigate corrosion and thus manage the integrity of pipes. Such detecting may assist in cost savings (such as by avoiding costly intervention), a reduction in lost production (such as when a well is offline due to pipe integrity issues), etc. Conventional approaches may require intervention operations to predict corrosion in fluid transportation systems. For example, wireline operations may be performed on a wellbore to obtain information to predict corrosion in one or more pipes of the wellbore. Such intervention operations may be cost and/or time intensive. Conventional approaches may negatively impact operational efficiency, safety measures, environmental protection, etc. Additionally, the interventions may result in unplanned shutdowns, production downtime, etc.

In some implementations, a hybrid model may be employed to predict corrosion and/or erosion on tubulars within a fluid transportation system without intervention operations. A hybrid model may include a physical mechanistic model and a learning machine. The mechanistic model may determine the mechanistic corrosion rate based on established chemical reaction processes. The learning machine may capture complex corrosion mechanisms not explicitly accounted for in the mechanistic model. The hybrid model may enhance the prediction of the corrosion in existing infrastructure and enable proactive measures to be taken to prevent future failures. The enhanced prediction of the corrosion rate may increase operational efficiency and/or reduce the environmental impact. For example, with the prediction via the hybrid model, unplanned shutdowns, production downtime and maintenance, costs, etc. may be reduced while in compliance with regulatory requirements.

Fluid transportation system data may first be obtained. The fluid system transportation system data may include data corresponding to one or more tubulars in the fluid transportation system and data relating to the fluid flowing through the tubulars. The fluid transportation system data may include pressure, temperature, flow rate, water cut, pipe inclination, pipe diameter, carbon dioxide (CO2) partial pressure, hydrogen sulfide (H2S) partial pressure, oil composition, solid content, etc. In some implementations, the mechanistic model may determine the mechanistic corrosion rate of a tubular in the fluid transportation system based on the fluid transportation system data. Concurrently (or subsequently), the fluid transportation system data may be input into a learning machine to determine the residual corrosion rate of a tubular in the fluid transportation system. Parameters such as oil composition and solid content, have been known to affect corrosion or erosion, but, in some implementations, may not be captured by the mechanistic model. Thus, the learning machine (such as a neural network) may be trained to determine the residual corrosion rate. The residual corrosion rate may represent the difference between the actual observed corrosion rate and the mechanistic corrosion rate. In some implementations, the learning machine may be trained on synthetic data, client-provided data (such as corrosion logs and corresponding fluid transportation system data), or any combination thereof. In some implementations, a correction factor may be applied to the residual corrosion rate output by the learning machine based on the learning machine's performance (e.g., a coefficient of determination (R²)). The final corrosion rate may then be determined by combining the mechanistic corrosion rate and the corrected residual corrosion rate.

This hybrid approach may leverage the strengths of both physical modeling and artificial intelligence (AI), enhancing corrosion prediction by incorporating known physics and addressing complex corrosion phenomena that are not fully understood. By training the learning machine to focus on residual corrosion, the model becomes more robust, concentrating only on the aspects not captured by the mechanistic model. Additionally, this approach ensures that the model remains effective even with limited training data for the neural network, continuously improving as more data becomes available.

Early detection and prevention of corrosion may result in proactive and/or faster maintenance, interventions, workover planning, etc. Thus, well availability may be maximized, and operating expenses may be reduced by avoiding unplanned shutdowns and repair costs. In some implementations, a well operation (or any other fluid transportations system operation) or attribute in a well may be modified or updated based on the final corrosion rate. For example, an operation (at the surface or downhole) may be performed and/or directed to be performed to change a well operation or attribute based final corrosion rate of a tubular in a wellbore. Well operations may include implementing a new chemical treatment, adjusting the chemical composition, injection, etc. currently treating a wellbore, adjusting a choke setting, removing and/or replacing one or more components (such as a string of tubing), etc. Examples of such attributes may include completion design (casing, tubing, etc.). For instance, a tubing in a well may be replaced with a tubing comprising different metallurgy that is able to withstand the corrosion in the well (as determined by the final corrosion rate), and/or the final corrosion rate may be utilized to optimize tubular types for future wells.

### Example Systems

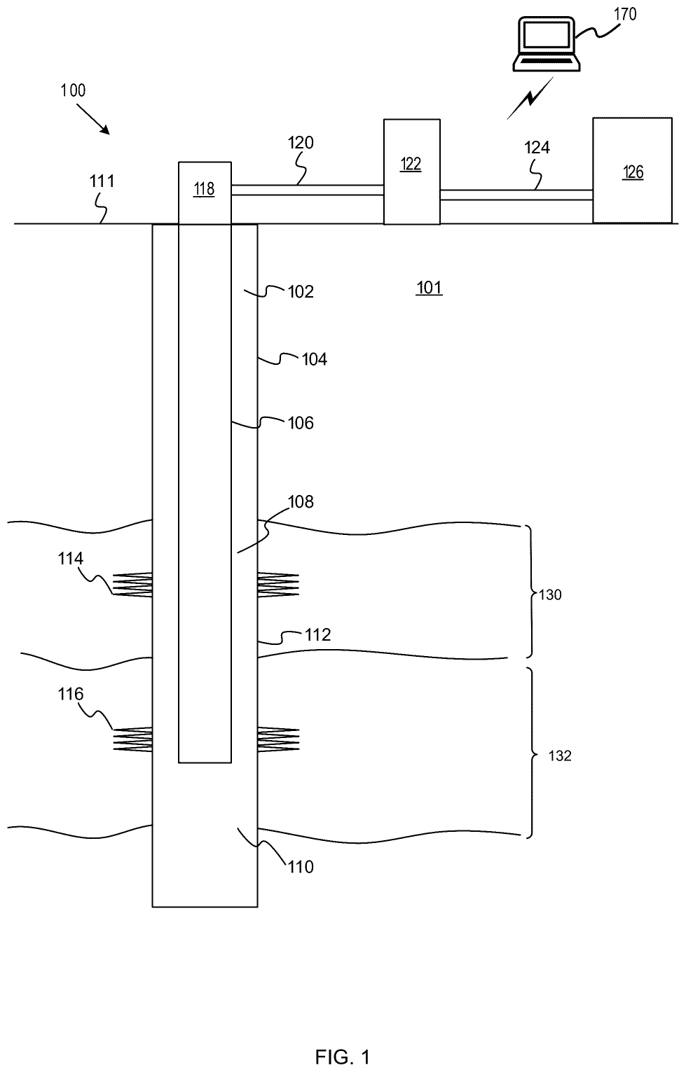

FIG. 1 is a diagrammatic illustration of an example well system, according to some implementations. In particular, a well system 100 of FIG. 1 includes a wellbore 102 in a subsurface formation 101. The wellbore 102 includes casing 104 and number of perforations 114, 116 being made in the casing 104. Each set of perforations 114, 116 is located in a respective reservoir 130, 132 to allow reservoir fluids (i.e., oil, water, and gas) from the respective reservoirs 130, 132 to flow into the wellbore 102 and into the tubular string 106 (the production tubing).

A flowline 120 coupled to the wellhead 118 of wellbore 102 and a separator 122 may allow the fluid produced up the tubular string 106 to flow to the separator 122. The separator 22 may be designed to separate the phases of the fluid produced from the wellbore 102. For instance, oil, water, and gas may be separated from each other after passing through the separator 122. The aggregate of fluid produced from wellbore 102 may then flow to a tank battery, via flowline 124, that may include components such as storage tank 126, to store the different phases of fluid in respective tanks. In some implementations, the respective fluids may then be transported via pipeline systems (not pictured) to other facilities for gathering and/or processing.

In some implementations, the fluid may include acidic acids such as carbon dioxide (CO2), hydrogen sulfide (H2S), etc. The acidic acids may dissolve in the water which may then corrode the pipes and other metal equipment such as the casing 104, tubular string 106, flowline 120, flowline 124, separator 122, storage tank 126, etc. In some implementations, one or more chemicals may be applied to wellbore 102 and/or other locations on or beneath the surface 111 to prevent and/or manage corrosion. For example, the chemicals may be applied down the wellbore 102, in the flowline 120, in the separator 122, in the storage tanks such as storage tank 126, downstream of the well system (such as fluid transportation infrastructure), etc. Alternatively, components, such as the tubular string 106, may be replaced if damaged from corrosion and/or as a preventative measure (such as to be replaced with a more corrosion-resistant pipe).

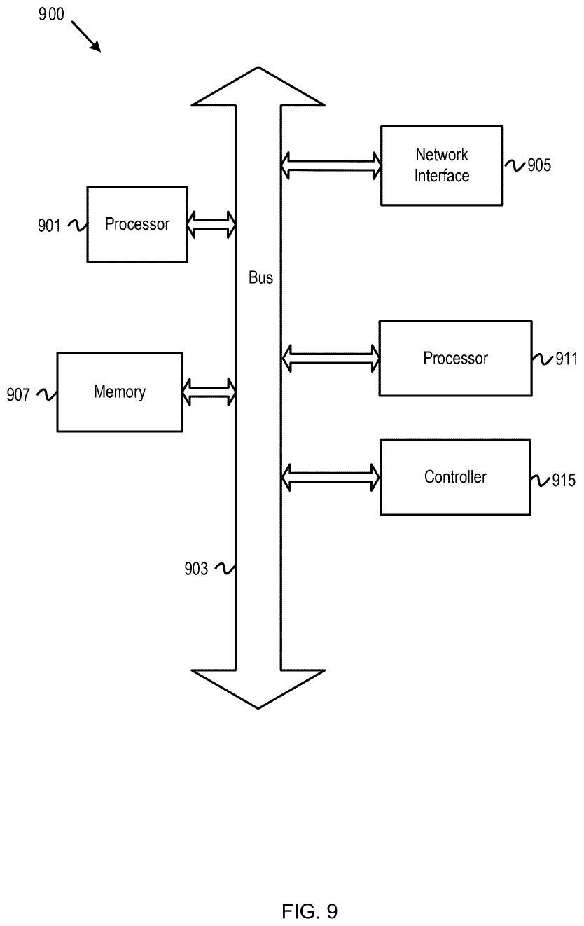

The well system 100 includes a computer 170 that may be communicatively coupled to other parts of the well system 100. The computer 170 may be local or remote to the well system 100. A processor of the computer 170 may perform simulations (as further described below). In some implementations, the processor of the computer 170 may control well operations of the well system 100 or subsequent well operations of other well systems. For instance, the processor of the computer 170 may obtain data corresponding to the operational conditions, production conditions, pipe specifications, etc. The processor of the computer 170 may be configured with a hybrid model (comprising a mechanistic model and a learning machine) to determine the final corrosion rate on tubulars in the well system 100. Additionally, the processor of the computer 170 may instruct well operations to be performed based on the final corrosion rate. An example of the computer 170 is depicted in FIG. 9, which is further described below.

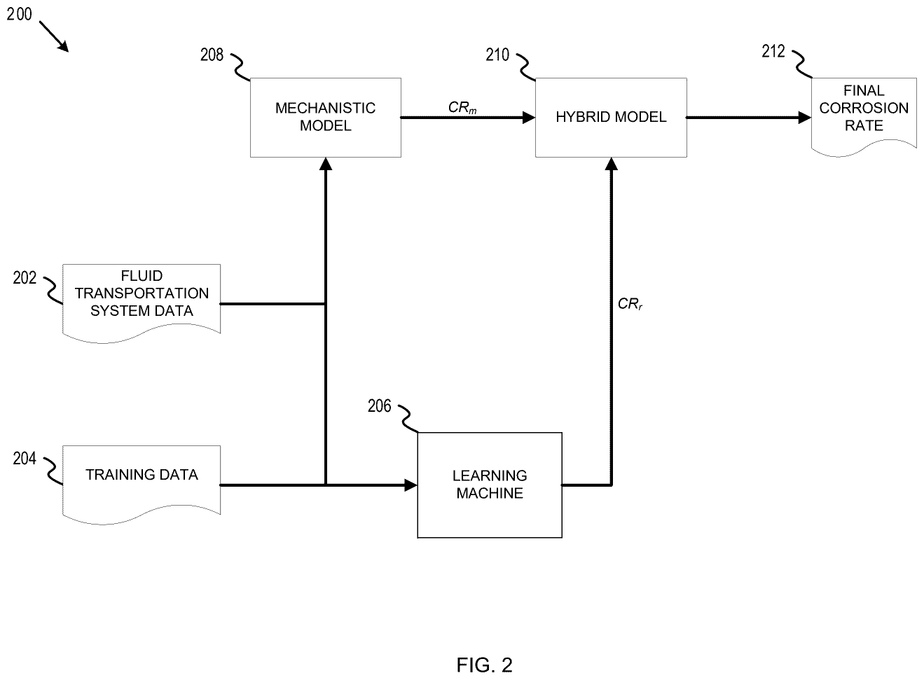

FIG. 2 is a block diagram of a hybrid approach for determining the final corrosion rate of a tubular, according to some implementations. FIG. 2 includes a tubular integrity management system 200 comprising a learning machine 206, a mechanistic model 208, and a hybrid model 210. Fluid transportation system data 202 may be obtained from a fluid transportation system (such as a wellbore, pipeline system, etc.). For example, fluid transportation system data 202 may correspond to a production tubing string in a wellbore. Fluid transportation system data 202 may include well information, geology information, well completion information, production information, etc. or any combination thereof. Well information may include well name, status (oil, gas, etc.), well type (production, injection, etc.), well configuration (vertical, deviated, horizontal, etc.), surface hole location coordinates, bottom hole location coordinates, kelly bushing (KB) elevation, well trajectory, etc. Geology information may include stratigraphic layering, formation properties (porosity, permeability, etc.), faults and fractures (if any), seismic activity (if any), formation fluid composition, water chemistry, logs (such as gamma ray, density, neutron porosity, resistivity, etc.), etc. Well completion information may include drilling date, completion date, tubular properties (such has casing/tubing outer diameter, inner diameter, weight, grade, alloy composition, yield strength, tensile strength, etc.), formation top and/or bottom, depth profiles (such as well depth, segment depths, etc.), perforation information, workover information, stimulation information, physical and corrosion resistance properties (such as corrosion rate), sand control, etc. Production information may include production rates (oil, water, gas, etc.), well test data, velocities (such as sand influx velocity, critical sand velocity, erosional velocity, etc.), operating conditions (such as temperature, pressure, pH levels, salinity, produced/injected fluid composition, etc.), fluid dynamics (such as fluid flow patterns, velocities, turbulence, etc.), artificial lift (if any), etc.

Fluid transportation system data 202 may be input into the mechanistic model 208 to generate a mechanistic corrosion rate (CRₘ) of a tubular. The mechanistic model 208 may include any suitable model (steady-state and/or transient) for predicting corrosion. In some implementations, the mechanistic model 208 may include a steady-state electrochemical corrosion model that predicts corrosion due to the presence of CO2 and/or H2S in aqueous solution. The mechanistic model 208 may be based on the bulk water chemistry parameters driving the electrochemical reactions.

In some implementations, the mechanistic model may include an algorithm to determine the mechanistic corrosion rate. The following are example modules that the mechanistic model 208 may be configured with to determine the mechanistic corrosion rate, and the mechanistic model 208 is not limited to the modules described herein. Any suitable algorithm or an ensemble of algorithms to capture multiple processes may be utilized to determine the mechanistic corrosion rate.

The algorithm of the mechanistic model 208 may include a wettability module to determine if conditions (indicated in the fluid transportation system data 202) allow for corrosion. When water cut is low (such as less than 20% for flow rates higher than 1 meter per second (m/s)), the water molecules may be fully entrained in the oil phase of the fluid, and no corrosion may occur. In some implementations, the determination of proper conditions may be based on empirical data as a function of maximum and critical droplet size. In some implementations, if the wettability module determines conditions do not allow for corrosion (e.g., water cut is below a threshold and/or flow rate is above a threshold), then the mechanistic model 208 may output a mechanistic corrosion rate of zero. If conditions do allow for corrosion, then the algorithm may proceed to a three layer stratified module.

The three layer stratified module may determine the film (i.e., phase layer) heights and respective in-situ velocities in the tubular. If conditions for corrosion are present, water droplets may coalesce and form a continuous later (wettability may change to water/mixed wet). Based on the mass and momentum balance of equations, the three layered stratified module may determine the film height and in-situ velocities. The films may include the oil phase, water phase, and emulsion phase (water-in-oil emulsion, oil-in-water emulsion).

The mechanistic module may then determine the concentration of ion species. Ion species may include species of CO2 (such as CO₂, H₂CO₃, HCO₃⁻, CO₃²⁻, OH⁻, H⁺), H2S (H⁺, OH⁻, H₂S, HS⁻, S²⁻), and others such as Fe²⁺, Cl—, Na+, etc. A kinetic module may then utilize the ion species to derive the total anodic current density.

A corrosion module may calculate the mechanistic corrosion rate (CRₘ) in millimeters per year (mm/yr) as a function of the anodic current density determined in the kinetic module, represented by Equation 1:

$${CR}_{m} = \frac{{i}_{α} {M}_{w , Fe}}{{ρ}_{Fe} n F} \qquad ( 1 )$$

Where iₐ is the anodic current density measured in amperes per square meter (A/m²), M_{w,Fe} is the atomic mass of iron (55.56 grams per mole (g/mol)), ρ_{Fe} is the density of iron (7,800 grams per cubic meter (g/m³)), and n is the number of electrons involved in iron oxidation (2 mole/mol). The mechanistic corrosion rate may then be input into the hybrid model 210, as described below.

The fluid transportation system data 202 may also be input into the learning machine 206 to generate the residual corrosion rate (CRᵣ). The learning machine 206 may be configured to accept inputs such as pressure, temperature, CO2 partial pressure, H2S partial pressure, diameter of the tubular, flow velocity, water cut, pH level, and other features not considered in the mechanistic model 208 such as oil composition, saturates, asphaltenes, resins, aromatics (SARA) components. Such components have been known to affect corrosion rate, but are not well understood nor included in mechanistic models. Thus, it may be captured via a trained learning machine, such as a neural network or any other suitable machine learning method.

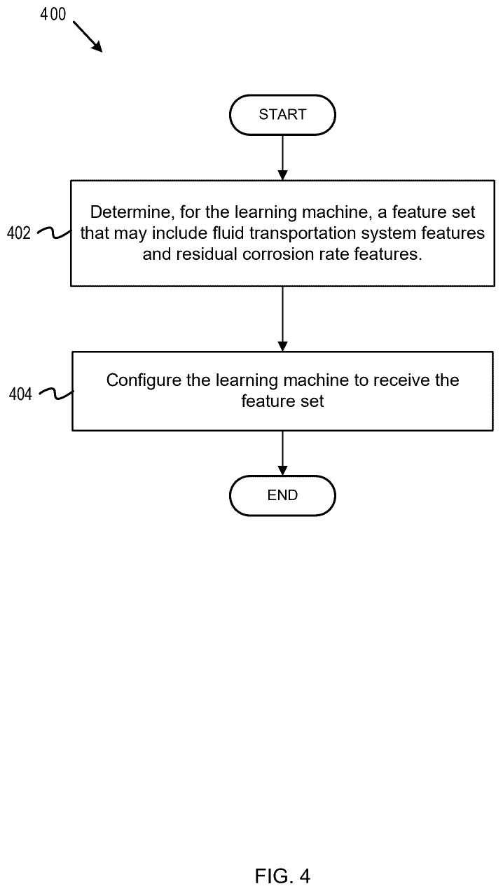

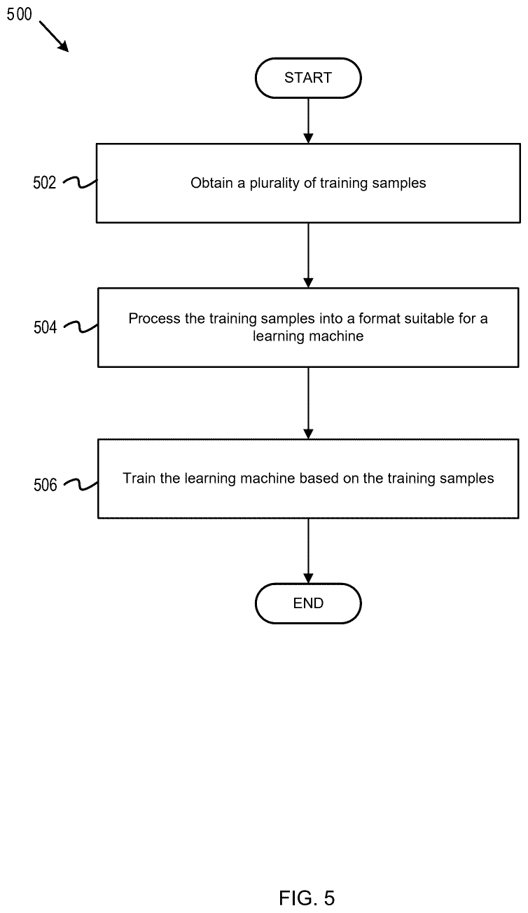

Training data 204 may be utilized to train the learning machine 206 to generate residual corrosion rate of a tubular. Configuration and training of the learning machine is described in FIGS. 4-5 below.

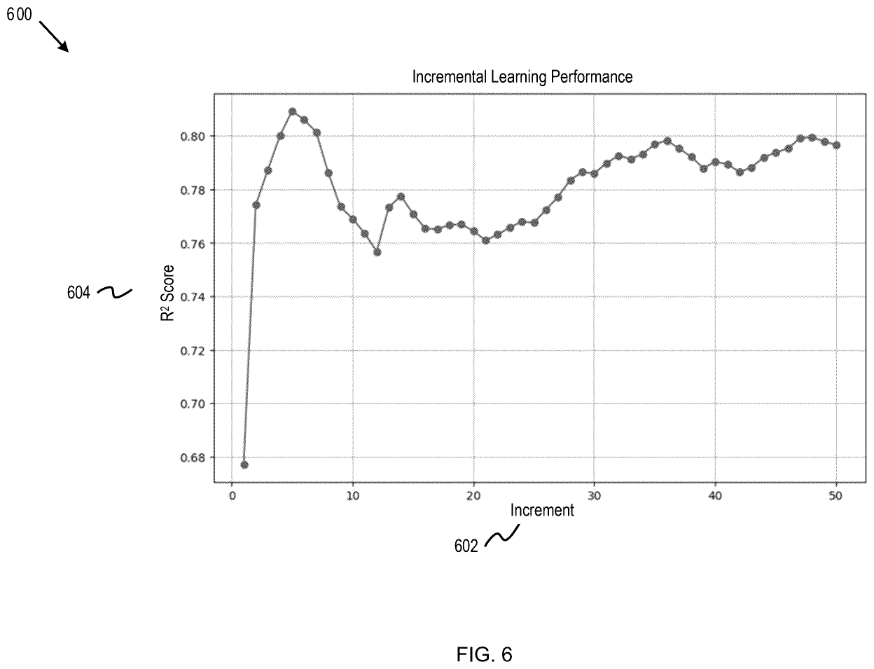

The mechanistic corrosion rate and the residual corrosion rate may be input into the hybrid model 210 to determine the final corrosion rate 212. The hybrid model 210 may be represented by Equation 2:

$${CR}_{h} = {CR}_{m} + {CR}_{r} * a \qquad ( 2 )$$

Where CRₕ is the final corrosion rate and a is a correction factor. The correction factor may be based on the performance of the learning machine. For example, the correction factor may be derived from the R² value of the current learning machine performance in regard to the training data to minimize the error between the neural network performance and the actual corrosion rate indicated in the training samples (as described in FIGS. 6-8).

### Example Operations

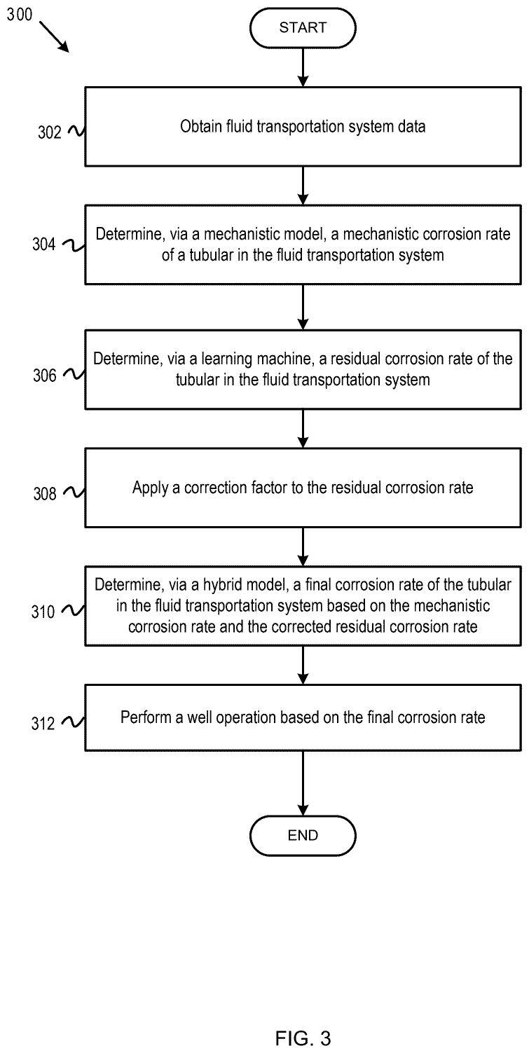

FIG. 3 is a flowchart of example operations for determining a final corrosion rate of a tubular, according to some implementations. FIG. 3 depicts a flowchart 300 of operations to determine the final corrosion rate of a tubular, via a mechanistic model and a learning machine, and perform a well operation based on the corrosion rate. The operations of the flowchart 300 may be repeated for each tubular in the fluid transportation system (such as for each casing string, tubing string, etc. that is transporting fluid). The operations of flowchart 300 are described in reference to the well system 100 and computer 170 of FIG. 1. Additionally, the mechanistic model, learning machine, and hybrid model described in the operations of the flowchart 300 are described in reference to the tubular integrity management system 200 of FIG. 2. Operations of the flowchart 300 begin at block 302.

At block 302, the processor of the computer 170 may obtain fluid transportation system data. The fluid transportation system data may include well information, geology information, well completion information, production information, etc. as described in FIG. 2. Fluid transportation system data may be obtained via sensors, logs, etc. The fluid transportation system data may include information corresponding to one or more tubulars in the system. For example, the data may include tubing data, casing data, flowline data, etc.

At block 304, the processor of the computer 170 may determine, via a mechanistic model, a mechanistic corrosion rate of a tubular in the fluid transportation system. The mechanistic model may be similar to the mechanistic model 208 utilized to determine the mechanistic corrosion rate as described in FIG. 2. For example, fluid transportation system data such as pressure, temperature, CO2 partial pressure, H2S partial pressure, diameter of the tubular, sodium chloride (NaCl) concentration, flow velocity, water cut, pH level, etc. may be input into the mechanistic model to determine if conditions allow for corrosion, and if so, determine the mechanistic corrosion rate due to the CO2 and H2S present in the fluid. Any suitable mechanistic model may be utilized to determine the mechanistic corrosion rate.

At block 306, the processor of the computer 170 may determine, via a learning machine, a residual corrosion rate of the tubular in the fluid transportation system. The learning machine may be similar to the learning machine 206 described in FIG. 2. For example, the learning machine may include features not considered in the mechanistic model (such as oil composition). The learning machine may be a neural network or any suitable supervised machine learning algorithm trained to determine residual corrosion rate of a tubular based on fluid transportation system data. Configuration and training of the learning machine are further described in FIGS. 4-5.

At block 308, the processor of the computer 170 may apply a correction factor to the residual corrosion rate. As previously described, the correction factor may be based on the current performance of the learning machine (described in FIGS. 6-8). A corrected residual corrosion rate may be generated when the correction factor is applied to the residual corrosion rate.

At block 310, the processor of the computer 170 may determine, via a hybrid model, a final corrosion rate of the tubular in the fluid transportation system based on the mechanistic corrosion rate and the corrected residual corrosion rate. As shown in Equation 2 above, the final corrosion rate may be the sum of the mechanistic corrosion rate and the corrected residual corrosion rate. In some implementations, the final corrosion rate may be utilized in nodal analysis to determine corrosion at various points along the tubular. For example, in a horizontal wellbore, the final corrosion rate may be determined at depth intervals along the curved section based on the fluid transportation system data (such as depth, inclination, azimuth, dogleg severity, etc.).

At block 312, the processor of the computer 170 may perform a well operation based on the final corrosion rate. As described above, a well operation may include planning and/or performing a workover operation to repair corroded pipe, replace tubulars with metallurgical properties more suitable to withstand the final corrosion rate, etc. Other operations may include modifying corrosion inhibitor chemical treatments (composition, schedule, etc.), modifying future completion designs, etc. In some implementations, the final corrosion rate may be displayed on a graphical user interface (GUI) of the computer 170 where a user may evaluate the final corrosion rate and plan/direct well operations and/or modifications to well attributes. For example, a two dimensional (2D) and/or a three-dimensional (3D) representation of the tubular with the final corrosion rate at a period of time may be displayed, a log of the corrosion at respective depths may be displayed, etc.

FIG. 4 is a flowchart depicting example operations to configure a learning machine, according to some implementations. FIG. 4 includes a flowchart 400 that may determine a feature set, and may configure the learning machine to receive the feature set as input. The learning machine may include any suitable learning machine such as a neural network. Operations of flowchart 500 of FIG. 5 are described in reference to the processor of the computer 170 of FIG. 1. Operations of the flowchart 400 start at block 402.

At block 402, the processor of the computer 170 may determine, for the learning machine, a feature set that may include fluid transportation system features and residual corrosion rate features. Fluid transportation system features may include features such as pressure, temperature, CO2 partial pressure, H2S partial pressure, diameter of the tubular, flow velocity, water cut, pH value, oil composition, etc. Residual corrosion rate features may include the residual corrosion rate of a tubular. In some implementations, the feature set may include other corrosion rate features such as the mechanistic corrosion rate and/or the final corrosion rate. Some implementations may utilize any suitable feature set including any suitable value related to the residual corrosion rate of a tubular and any suitable value related to the fluid transportation system.

At block 404, the processor of the computer 170 may configure the learning machine to receive the feature set as input. As noted, the features may include fluid transportation system features and residual corrosion rate features. The flowchart 500 ends after block 504. In some implementations, when the learning machine comprises a neural network, the learning machine may be configured with one or more layers. For example, the learning machine may be configured as a five-layer incremental learning neural network. A first layer may include a fully connected layer that receives input features and outputs, for example, 128 neurons. A second layer may be a fully connected layer the takes the 128 neurons and outputs, for example, 64 neurons. A third layer may be a fully connected layer the takes the 64 neurons and outputs, for example, 32 neurons. A fourth layer may be a fully connected layer the takes the 32 neurons and outputs, for example, 16 neurons. A fifth layer may be a fully connected layer the takes the 16 neurons and outputs the predicted residual corrosion rate. Some implementations may utilize any suitable configuration including any suitable layer count, layer type (convolutional layers, fully connected layers), and number of neurons input/output in each layer.

After block 404, the learning machine may begin training itself based on training samples. The discussion of FIG. 5 provides additional details about training samples and training the learning machine.

FIG. 5 is a flowchart depicting example operations to train a learning machine, according to some implementations. FIG. 5 includes a flowchart 500 that may train a supervised learning machine with training samples. Operations of flowchart 500 of FIG. 5 are described in reference to the processor of the computer 170 of FIG. 1. Operations of the flowchart 500 start at block 502.

At block 502, the processor of the computer 170 may obtain a plurality of training samples. The training samples may ensure the learning machine's capability to generate a residual corrosion rate based on the fluid transportation system data. The training samples may include fluid transportation system data samples and residual corrosion rate samples derived by finding the difference between actual corrosion values obtained from wireline corrosion logs and corrosion derived from the mechanistic corrosion model. Some implementations may utilize any suitable technique to obtain training samples. The training samples may be obtained from historical data such as logs, offset well data, etc. The training samples may be generated by software and systems based on the system level design, numerical modeling, sample measurements, etc. For example, real data may not be available. Thus, simulation data may be utilized as training data. For instance, advanced models may be configured to account for both mechanistic corrosion rate and other complex corrosion characteristics such as the formation of protective layers (i.e., scale) on steel surfaces. Scale growth on the tubular walls over time may have a complex, non-linear impact on the corrosion rate. The simulation may generate a plurality of training samples (i.e., fluid transportation system samples and corresponding final corrosion at various conditions.

At block 504, the processor of the computer 170 may process the training samples into a format suitable for a learning machine. For instance, if the learning machine is configured to accept inputs with values between 0 and 1, the fluid property sample may be scaled to values between 0 and 1. In some implementations, random noise may be added to the training samples to simulate “real” data. Processing may include deriving the residual corrosion rate samples. For example, the fluid transportation system samples may be input into a mechanistic model (such as mechanistic model 208 of FIG. 2) to generate the mechanistic corrosion rate. The difference between the mechanistic corrosion rate and the final corrosion rate generated by the simulation may be the residual corrosion rate samples to be utilized in training the learning machine.

At block 506, the processor of the computer 170 may train the learning machine based on the training samples. The learning machine may use fewer than all the training samples in its training process. For example, the learning machine may utilize 80% of the training samples at block 504. Later, the learning machine may use the remaining 20% of the training samples to test the learning machine. The learning machine may be updated (i.e., trained) as new training samples are obtained. For instance, the learning machine be trained with updated training samples obtained from synthetic data, historical testing data, etc. In some implementations, the learning machine may be run to predict the residual corrosion rate with the test data (fluid transportation system samples) to evaluate the performance of the learning machine, and subsequently generate and apply the correction factor to accommodate for the lack of performance (if any).

To help illustrate, FIGS. 6-8 include charts depicting training samples with synthetic data, and the performance of the learning machine as it is trained. FIG. 6 is a chart depicting the incremental learning performance of a learning machine, according to some implementations. FIG. 6 includes a chart 600 with an x-axis 602 and a y-axis 604. The x-axis 602 is the training increment and the y-axis 604 is the R² score. Initially learning model performance seems to be performing well from approximately increment 1 to 5. This may be due to a low variation in data (small training set), e.g., the range of input variables and their equivalent corrosion is relatively small. As more training data is acquired the learning model initially performs worse (increments 6-20) because the data variation increases (by introducing more training data). The model gradually learns the new variation stabilizing at an R² value of approximately 0.80.

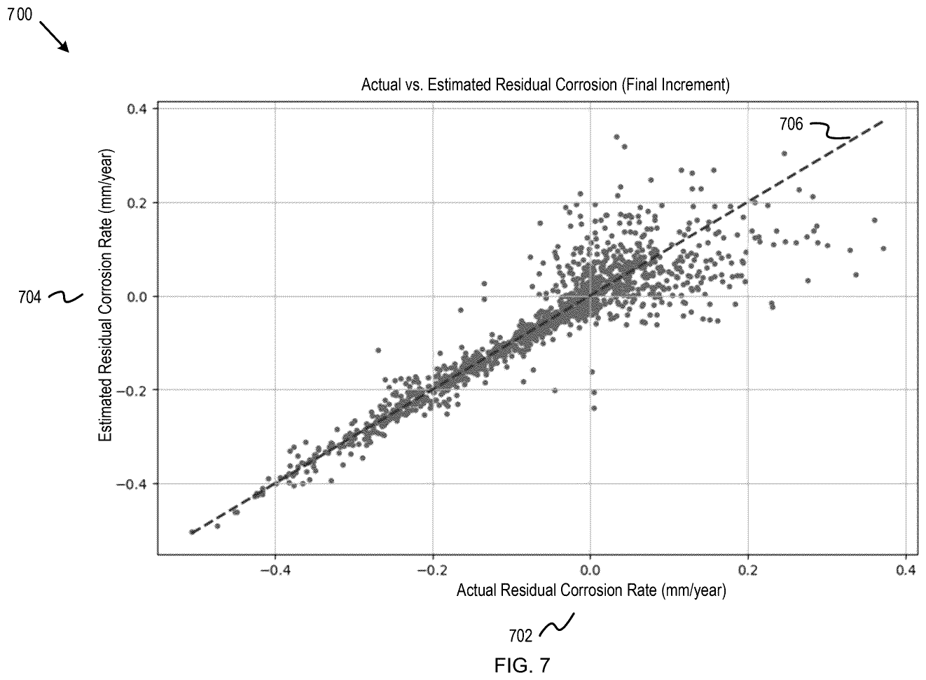

FIG. 7 is a chart depicting the performance of a learning machine, according to some implementations. In particular FIG. 7 includes a chart 700 that depicts actual versus estimated residual corrosion rates generated by a learning machine. The chart 700 includes an x-axis 702 and a y-axis 704. The x-axis 702 is the actual residual corrosion rate in millimeters per year (mm/year). Some implementations may use the simulation results described in block 504 of FIG. 5 as the actual residual corrosion rate. The y-axis 704 is the estimated residual corrosion rate output by the learning machine in millimeters per year (mm/year). The estimated residual corrosion rates may be the output from the test data set using the model trained to the final increment of the incremental training, such as increment 50 in FIG. 6. The learning machine is exceptional at predicting negative residual corrosions (when residual corrosion rate is less than zero on the x-axis 702 and y-axis 704 (as shown by the correlation between the actual and estimated residual corrosion rate with respect to the line of best fit 706). The residual corrosion is negative when the process of scale buildup which acts as a protective layer is a dominant factor. However, the learning machine does a poor job (low correlation with respect to the line of best fit 706) when the residual corrosion is positive. This may occur where there are other mechanisms that are more domineering than the buildup of scale. This may indicate that these mechanisms in the simulation may not be properly captured.

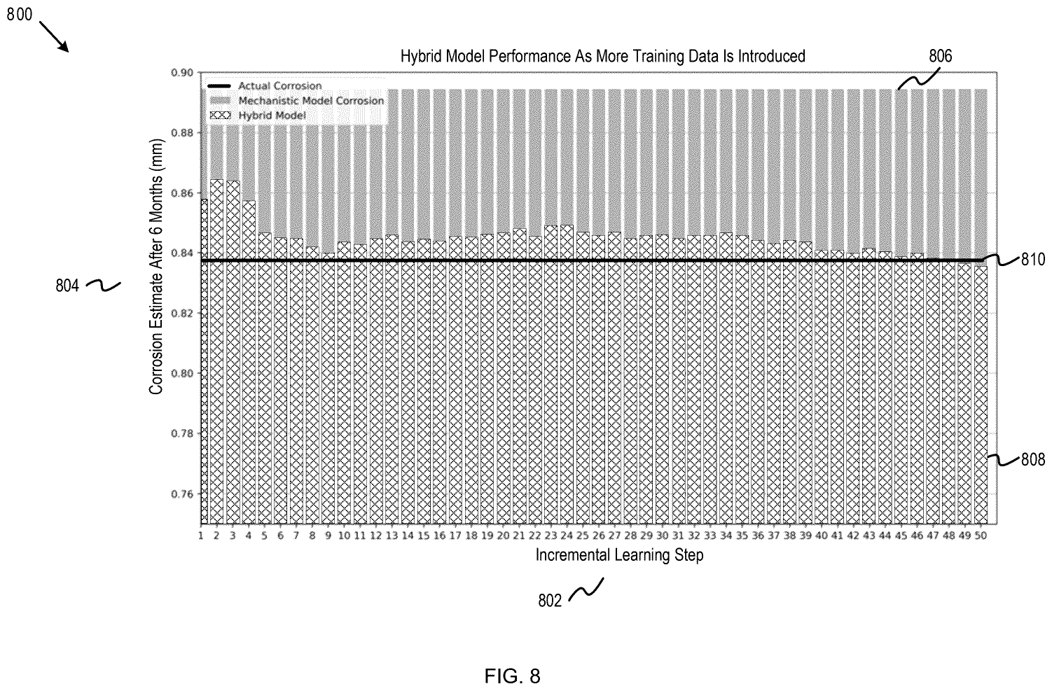

FIG. 8 is a chart depicting the performance of a learning machine, according to some implementations. In particular FIG. 8 includes a chart 800 of the performance of the learning machine as more training data is introduced. The chart 800 includes an x-axis 802 and a y-axis 804. The x-axis 802 is the incremental learning step (similar to the increments on x-axis 602 of FIG. 2). The y-axis 804 is the corrosion estimation after 6 months in millimeters (mm). The chart 800 includes the mechanistic corrosion 806 (generated by a mechanistic model), the final corrosion rate 808 generated by the hybrid model (mechanistic corrosion plus corrected residual corrosion) (generated by a learning machine), and the actual corrosion rate 810. Applying the correction factor helps minimize the error impact when the learning machine performance is poor (such as when the correlation between the estimated and actual residual corrosion rate is low with respect to the line of best fit 706 of FIG. 7). As the model learns (increments increase) the learning machine performance improves (i.e., the final corrosion rate 808 with the hybrid model is approximately similar to the actual corrosion rate 810). This illustrates that the concept of including a learning machine to learn residual corrosion improves overall corrosion estimate. In some implementations, when the learning machine is updated/re-trained with updated data, the performance of the learning machine may be reevaluated to obtain an updated correction factor.

While the aspects of the disclosure are described with reference to various implementations and exploitations, it will be understood that these aspects are illustrative and that the scope of the claims is not limited to them. In general, determining final corrosion rate of a tubular via a learning machine and mechanistic model as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein but are to be accorded the widest scope consistent with this disclosure, the principles and the novel features disclosed herein.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example process in the form of a flow diagram. However, some operations may be omitted and/or other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described should not be understood as requiring such separation in all implementations, and the described program components and systems may generally be integrated together in a single software product or packaged into multiple software products. Additionally, other implementations are within the scope of the following claims. In some cases, the actions recited in the claims may be performed in a different order and still achieve desirable results.

### Example Computer

FIG. 9 is a block diagram depicting an example computer, according to some implementations. FIG. 9 depicts a computer 900 for determining a final corrosion rate of a tubular. The computer 900 includes a processor 901 (possibly including multiple processors, multiple cores, multiple nodes, and/or implementing multi-threading, etc.). The computer 900 includes memory 907. The memory 907 may be system memory or any one or more of the above already described possible realizations of machine-readable media. The computer 900 also includes a bus 903 and a network interface 905. The computer 900 can communicate via transmissions to and/or from remote devices via the network interface 905 in accordance with a network protocol corresponding to the type of network interface, whether wired or wireless and depending upon the carrying medium. In addition, a communication or transmission can involve other layers of a communication protocol and or communication protocol suites (e.g., transmission control protocol, Internet Protocol, user datagram protocol, virtual private network protocols, etc.).

The computer 900 also includes a processor 911 and a controller 915 which may perform the operations described herein. For example, the processor 911 may obtain fluid transportation system data and determine, via a hybrid model, a final corrosion rate of a tubular. The controller 915 may perform an operation based on the final corrosion rate of the tubular, such as modifying a workover operation. The processor 911 and the controller 915 can be in communication. Any one of the previously described functionalities may be partially (or entirely) implemented in hardware and/or on the processor 901. For example, the functionality may be implemented with an application specific integrated circuit, in logic implemented in the processor 901, in a co-processor on a peripheral device or card, etc. Further, realizations may include fewer or additional components not illustrated in FIG. 9 (e.g., video cards, audio cards, additional network interfaces, peripheral devices, etc.). The processor 901 and the network interface 905 are coupled to the bus 903. Although illustrated as being coupled to the bus 903, the memory 907 may be coupled to the processor 901.

### EXAMPLE IMPLEMENTATIONS

Implementation #1: A method for managing integrity of a tubular comprising: obtaining fluid transportation system data, wherein the tubular is a component within a fluid transportation system; determining, via a mechanistic model, a mechanistic corrosion rate of the tubular based on the fluid transportation system data; determining, via a learning machine, a residual corrosion rate of the tubular based on the fluid transportation system data; and determining, via a hybrid model, a final corrosion rate of the tubular based on the mechanistic corrosion rate and the residual corrosion rate.

Implementation #2: The method of Implementation #1 further comprising: applying a correction factor to the residual corrosion rate to generate a corrected residual corrosion rate.

Implementation #3: The method of Implementation #2, wherein the corrected residual corrosion rate is added to the mechanistic corrosion rate to determine the final corrosion rate of the tubular.

Implementation #4: The method of any one or more of Implementation #1-3, wherein the fluid transportation system data includes well information, geology information, well completion information, production information, or any combination thereof.

Implementation #5: The method of any one or more of Implementation #1-4 further comprising: determining, for the learning machine, a feature set including a fluid transportation system feature and a residual corrosion rate feature; and configuring the learning machine to receive the feature set as input.

Implementation #6: The method of any one or more of Implementation #1-5 further comprising: training the learning machine to generate the residual corrosion rate based on a plurality of training samples, the training samples including fluid transportation system data samples and residual corrosion rate samples.

Implementation #7: The method of any one or more of Implementation #1-6, wherein at least one of a well operation or a well attribute is modified based on the final corrosion rate.

Implementation #8: The method of any one or more of Implementation #1-7, wherein the tubular is on the Earth's surface or beneath the Earth's surface, and wherein the fluid transportation system includes a wellbore, a production gathering system, a pipeline system, or any combination thereof.

Implementation #9: A system comprising: a tubular within a fluid transportation system; a processor; and a computer-readable medium having instructions stored thereon that are executable by the processor, the instructions including, instructions to obtain fluid transportation system data; instructions to determine, via a mechanistic model, a mechanistic corrosion rate of the tubular based on the fluid transportation system data; instructions to determine, via a learning machine, a residual corrosion rate of the tubular based on the fluid transportation system data; and instructions to determine a final corrosion rate of the tubular based on the mechanistic corrosion rate and the residual corrosion rate.

Implementation #10: The system of Implementation #9 further comprising: instructions to apply a correction factor to the residual corrosion rate to generate a corrected residual corrosion rate.

Implementation #11: The system of Implementation #10, wherein the corrected residual corrosion rate is added to the mechanistic corrosion rate to determine the final corrosion rate of the tubular.

Implementation #12: The system of any one or more of Implementation #9-11, wherein the fluid transportation system data includes well information, geology information, well completion information, production information, or any combination thereof.

Implementation #13: The system of any one or more of Implementation #9-12 further comprising: instructions to determine, for the learning machine, a feature set including a fluid transportation system feature and a residual corrosion rate feature; and instructions to configure the learning machine to receive the feature set as input.

Implementation #14: The system of any one or more of Implementation #9-13 further comprising: instructions to train the learning machine to generate the residual corrosion rate based on a plurality of training samples, the training samples including fluid transportation system samples and residual corrosion rate samples.

Implementation #15: The system of any one or more of Implementation #9-14, further comprising: instructions to direct an operation to modify at least one of a well operation or a well attribute based on the final corrosion rate.

Implementation #16: A non-transitory, computer-readable medium having instructions stored thereon that are executable by a processor, the instructions comprising: instructions to obtain fluid transportation system data, wherein a tubular is a component of a fluid transportation system; instructions to determine, via a mechanistic model, a mechanistic corrosion rate of the tubular based on the fluid transportation system data; instructions to determine, via a learning machine, a residual corrosion rate based on the fluid transportation system data; and instructions to determine a final corrosion rate of the tubular based on the mechanistic corrosion rate and the residual corrosion rate.

Implementation #17: The non-transitory, computer-readable medium of Implementation #16 further comprising: instructions to apply a correction factor to the residual corrosion rate to generate a corrected residual corrosion rate.

Implementation #18: The non-transitory, computer-readable medium of Implementation #17, wherein the corrected residual corrosion rate is added to the mechanistic corrosion rate to determine the final corrosion rate of the tubular.

Implementation #19: The non-transitory, computer-readable medium of any one or more of Implementation #16-18, wherein the fluid transportation system data includes well information, geology information, well completion information, production information, or any combination thereof.

Implementation #20: The non-transitory, computer-readable medium of any one or more of Implementation #16-19 further comprising: instructions to modify at least one of a well operations or a well attribute based on the final corrosion rate.

Use of the phrase “at least one of” preceding a list with the conjunction “and” should not be treated as an exclusive list and should not be construed as a list of categories with one item from each category, unless specifically stated otherwise. A clause that recites “at least one of A, B, and C” can be infringed with only one of the listed items, multiple of the listed items, and one or more of the items in the list and another item not listed.

As used herein, the term “or” is inclusive unless otherwise explicitly noted. Thus, the phrase “at least one of A, B, or C” is satisfied by any element from the set {A, B, C} or any combination thereof, including multiples of any element.

1. A method for managing integrity of a tubular comprising:
obtaining fluid transportation system data, wherein the tubular is a component within a fluid transportation system;
determining, via a mechanistic model, a mechanistic corrosion rate of the tubular based on the fluid transportation system data;
determining, via a learning machine, a residual corrosion rate of the tubular based on the fluid transportation system data; and
determining, via a hybrid model, a final corrosion rate of the tubular based on the mechanistic corrosion rate and the residual corrosion rate.

2. The method of claim 1 further comprising:
applying a correction factor to the residual corrosion rate to generate a corrected residual corrosion rate.

3. The method of claim 2, wherein the corrected residual corrosion rate is added to the mechanistic corrosion rate to determine the final corrosion rate of the tubular.

4. The method of claim 1, wherein the fluid transportation system data includes well information, geology information, well completion information, production information, or any combination thereof.

5. The method of claim 1 further comprising:
determining, for the learning machine, a feature set including a fluid transportation system feature and a residual corrosion rate feature; and
configuring the learning machine to receive the feature set as input.

6. The method of claim 1 further comprising:
training the learning machine to generate the residual corrosion rate based on a plurality of training samples, the training samples including fluid transportation system data samples and residual corrosion rate samples.

7. The method of claim 1, wherein at least one of a well operation or a well attribute is modified based on the final corrosion rate.

8. The method of claim 1, wherein the tubular is on the Earth's surface or beneath the Earth's surface, and wherein the fluid transportation system includes a wellbore, a production gathering system, a pipeline system, or any combination thereof.

9. A system comprising:
a tubular within a fluid transportation system;
a processor; and
a computer-readable medium having instructions stored thereon that are executable by the processor, the instructions including,
instructions to obtain fluid transportation system data;
instructions to determine, via a mechanistic model, a mechanistic corrosion rate of the tubular based on the fluid transportation system data;
instructions to determine, via a learning machine, a residual corrosion rate of the tubular based on the fluid transportation system data; and
instructions to determine a final corrosion rate of the tubular based on the mechanistic corrosion rate and the residual corrosion rate.

10. The system of claim 9 further comprising:
instructions to apply a correction factor to the residual corrosion rate to generate a corrected residual corrosion rate.

11. The system of claim 10, wherein the corrected residual corrosion rate is added to the mechanistic corrosion rate to determine the final corrosion rate of the tubular.

12. The system of claim 9, wherein the fluid transportation system data includes well information, geology information, well completion information, production information, or any combination thereof.

13. The system of claim 9 further comprising:
instructions to determine, for the learning machine, a feature set including a fluid transportation system feature and a residual corrosion rate feature; and
instructions to configure the learning machine to receive the feature set as input.

14. The system of claim 9 further comprising:
instructions to train the learning machine to generate the residual corrosion rate based on a plurality of training samples, the training samples including fluid transportation system samples and residual corrosion rate samples.

15. The system of claim 9, further comprising:
instructions to direct an operation to modify at least one of a well operation or a well attribute based on the final corrosion rate.

16. A non-transitory, computer-readable medium having instructions stored thereon that are executable by a processor, the instructions comprising:
instructions to obtain fluid transportation system data, wherein a tubular is a component of a fluid transportation system;
instructions to determine, via a mechanistic model, a mechanistic corrosion rate of the tubular based on the fluid transportation system data;
instructions to determine, via a learning machine, a residual corrosion rate based on the fluid transportation system data; and
instructions to determine a final corrosion rate of the tubular based on the mechanistic corrosion rate and the residual corrosion rate.

17. The non-transitory, computer-readable medium of claim 16 further comprising:
instructions to apply a correction factor to the residual corrosion rate to generate a corrected residual corrosion rate.

18. The non-transitory, computer-readable medium of claim 17, wherein the corrected residual corrosion rate is added to the mechanistic corrosion rate to determine the final corrosion rate of the tubular.

19. The non-transitory, computer-readable medium of claim 16, wherein the fluid transportation system data includes well information, geology information, well completion information, production information, or any combination thereof.

20. The non-transitory, computer-readable medium of claim 16, further comprising:
instructions to modify at least one of a well operations or a well attribute based on the final corrosion rate.
